(19) United States
(12) Patent Application Publication
(10) Pub. No.: US 2015/0346391 A1
(43) Pub. Date: Dec. 3, 2015

(54) METHOD FOR FORMING ANTI STICTION COATING AND ANTI STICTION COATING THEREOF

(71) Applicant: Himax Display, Inc., Tainan City (TW)

(72) Inventor: Roland V. Gelder, Tainan City (TW)

(73) Assignee: Himax Display, Inc., Tainan City (TW)

(21) Appl. No.: 14/287,736

(22) Filed: May 27, 2014

(51) Int. Cl. G02B 1/16; G02B 1/12; B81C 1/00; G02B 26/08

(52) U.S. Cl. CPC G02B 1/16; G02B 26/0833; G02B 1/12; B81C 1/00992; B81C 2201/112

(57) ABSTRACT

A method for forming an anti-stiction coating on a surface of a semiconductor device is provided. Using atomic layer deposition (ALD) processes to activate surface prior to anti-stiction coating deposition, anti-stiction coating having strong chemical bonding to the surface is obtained.

### BACKGROUND

1. Technical Field

The application is related to a fabrication process of an electronic device. Particularly, the application is related to a method for forming an anti-stiction coating and the coating formed thereby.

2. Related Art

It is essential for the nowadays electronic products to be multi-functional and the electronic products configured with optical elements or devices are prevalent. Micro-electro-mechanical system (MEMS) devices, especially micromirror arrays, are widely utilized in many optical devices or vision products, such as large-scale projection engines, portable projectors, zoom lenses or even holographic displays.

For MEMS devices, a well-known problem is stiction, which occurs when surface adhesion forces are higher than the mechanical restoring forces of the micro-structure(s). The difficulty in alleviating the stiction is a critical impediment to the fabrication and operation of many MEMS devices.

### SUMMARY

The present invention directs to a method for treating a surface of a semiconductor device is provided. The surface treating method of the device includes using atomic layer deposition (ALD) processes to provide surface activation prior to anti-stiction coating (ASC) deposition, so as to create an environment for strong chemical bonding of anti-stiction coating to the surface. Also, the present invention provides a method for forming an anti-stiction coating on a surface of a semiconductor device and the anti-stiction coating fabricated thereby are provided.

The present invention provides a method for forming an anti-stiction coating on a surface of a semiconductor device. After providing the surface of the semiconductor device to a reaction chamber, an atomic layer deposition (ALD) process is performed to the semiconductor device. The atomic layer deposition process is performed with alternating reaction cycles of trimethylaluminum (TMA) and water (H2O) for depositing an aluminum oxide film on the surface of the semiconductor device in the reaction chamber. The ALD process is terminated with one TMA cycle to create a reactive surface within the reaction chamber. After at least one fluorinated species is provided to the reaction chamber, an anti-stiction coating is formed on the surface of the semiconductor device through reactions of the fluorinated species and TMA.

The present invention provides a method for forming an anti-stiction coating on a surface of a semiconductor device. After providing the surface of the semiconductor device to a first reaction chamber, an atomic layer deposition (ALD) process is performed to the semiconductor device. The atomic layer deposition process is performed with alternating reaction cycles of trimethylaluminum (TMA) and water (H₂O) for depositing an aluminum oxide film on the surface of the semiconductor device in the first reaction chamber. The ALD process is terminated with one H₂O cycle within the first reaction chamber. At least one TMA cycle of the ALD process is performed to the surface of the device to create a reactive surface in a second reaction chamber. After at least one fluorinated species is provided to the second reaction chamber, an anti-stiction coating is formed on the surface of the semiconductor device through the reaction of the fluorinated species and TMA.

According to the embodiments, anti-stiction coatings on a surface of a semiconductor device obtained through the above-mentioned methods are also provided.

In order to make the aforementioned and other features and advantages of the application comprehensible, several exemplary embodiments accompanied with figures are described in detail below.

### BRIEF DESCRIPTION OF THE DRAWINGS

The accompanying drawings are included to provide a further understanding of the application, and are incorporated in and constitute a part of this specification. The drawings illustrate embodiments of the application and, together with the description, serve to explain the principles of the application.

FIG. 1 is a flowchart illustrating a method for forming an anti-stiction coating on a surface of a semiconductor device according to one embodiment of the invention.

FIG. 2 is a flowchart illustrating a method for forming an anti-stiction coating on a surface of a semiconductor device according to another embodiment of the invention.

### DETAILED DESCRIPTION OF DISCLOSED EMBODIMENTS

One attractive approach to tackle the stiction problem is to provide a low-energy surface coating to the surface of the MEMS device(s), and the coating may help lower the surface energy and reduce capillary forces or electro-static forces acted upon the surface. The MEMS device(s) preferably is a MEMS micromirror array, for example.

In view of the importance of the anti-stiction coating in MEMS device(s), a method for treating a surface of a semiconductor device (e.g. a MEMS device) is provided. The surface treating method of the device includes using atomic layer deposition (ALD) processes to provide surface activation prior to anti-stiction coating deposition, so as to create an environment for strong chemical bonding of ASC to the surface. Also, a method for forming an anti-stiction coating on a surface of a semiconductor device (e.g. a MEMS device) and the anti-stiction coating fabricated thereby are provided.

This invention provides an anti-stiction coating (ASC) by forming self-assembled monolayers (SAMs) on the metal oxide terminated surface of a MEMS device. As the anti-stiction coating of the present invention is formed on the predetermined surface(s) through chemical bonding, the bonding is stronger and the obtained anti-stiction coating (ASC) capable of lowering the surface energy becomes more durable. Because the ASC provided by the present invention is adhered to the predetermined surface(s) of a MEMS device with stronger chemical bonding, the ASC provided by this invention is more resistant to degradation or wear after continuous operation.

The anti-stiction coating may be formed by fluorinated species reacted with activated metal oxide surface to form self-assembled monolayers (SAMs). The fluorinated species in general includes at least one or more carboxyl groups (—COOH) and may be exemplified by 2,2,3,3,4,4,5,5,6,6,7,7,8,8,9,9,10,10,10-nonadecafluorodecanoic acid, also called perfluorodecanoic acid (PFDA).

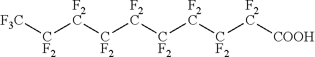 [SMILES: O=C(O)C(F)(F)C(F)(F)C(F)(F)C(F)(F)C(F)(F)C(F)(F)C(F)(F)C(F)(F)C(F)(F)F]

In the embodiment, at least one aluminum oxide (Al₂O₃) film may be deposited to the predetermined surface of the MEMS device by atomic layer deposition (ALD) in a ALD reaction chamber with alternating exposures of Al(CH₃)₃ (trimethylaluminum, TMA) and H₂O. The aluminum oxide (Al₂O₃) film deposited by ALD may be coated to any applicable substrate, including a semiconductor substrate (such as the substrate of silicon or germanium, gallium arsenide or indium phosphide) or a polymeric substrate. Preferably, the aluminum oxide (Al₂O₃) film is deposited by ALD over a silicon substrate formed with one or more MEMS device and onto a surface of the MEMS device.

In one embodiment, in a reaction chamber, the ALD process is performed using alternating exposures (i.e. alternating cycles) of TMA (trimethylaluminum, Al(CH₃)₃) and H₂O for depositing the aluminum oxide (Al₂O₃) film on a surface of a MEMS device. The ALD process is terminated with the exposure of TMA (i.e. TMA cycle), so that the deposited surface of the MEMS device is activated and a reactive surface is created. Taking the deposition of TMA on a hydroxylated aluminum surface as an example, the chemical reaction of TMA (Al(CH₃)₃) is summarized as follows. If the ALD process is terminated with the TMA cycle, the hydroxylated aluminum surface reacts with TMA and one methyl group of TMA coupled with hydrogen (H) of the hydroxyl group (—OH) to form methane gas (CH₄). Herein, TMA (Al(CH₃)₃) losing one methyl group is denoted as dimethylaluminum, DMA, (Al(CH₃)₂). In this case, the aluminum (Al) atom of (Al(CH₃)₂) is bonded to the remaining oxygen of the hydroxyl group of the hydroxylated aluminum surface, while the remaining two methyl groups of (Al(CH₃)₂) are available for the next step to react with the carboxyl group (—COOH) of the fluorinated species to form a bidentate chemical bond. In other words, the surface of the MEMS device is activated and a reactive surface terminated with DMA is created. Later the fluorinated species is provided to the reaction chamber. The carboxyl group (—COOH) of the fluorinated species can react with available methyl groups of DMA (Al(CH₃)₂) on the reactive surface to form a COO—Al bidentate chemical bonding there-between, so that a self-assembled monolayer (SAM) of the fluorinated species is formed and functions as the anti-stiction coating on the MEMS device surface. In this way, the anti-stiction coating formed through relatively strong bonding on the surface of the MEMS device is established.

In the above embodiment, it is noted that the reactive surface can not be exposed to air or an ambient environment until the deposition of the anti-stiction coating is completed. It is because that the reactive surface covered with excess TMA can not be exposed to ambient air, since this will cause the reactive surface to degrade. That is, the ALD process and the ASC coating process (ASC deposition process) may be performed in the different reaction chamber but the device or substrate must be transferred in a controlled environment between the two chambers. Within the controlled environment, the device or the substrate will not be exposed to air or an ambient environment.

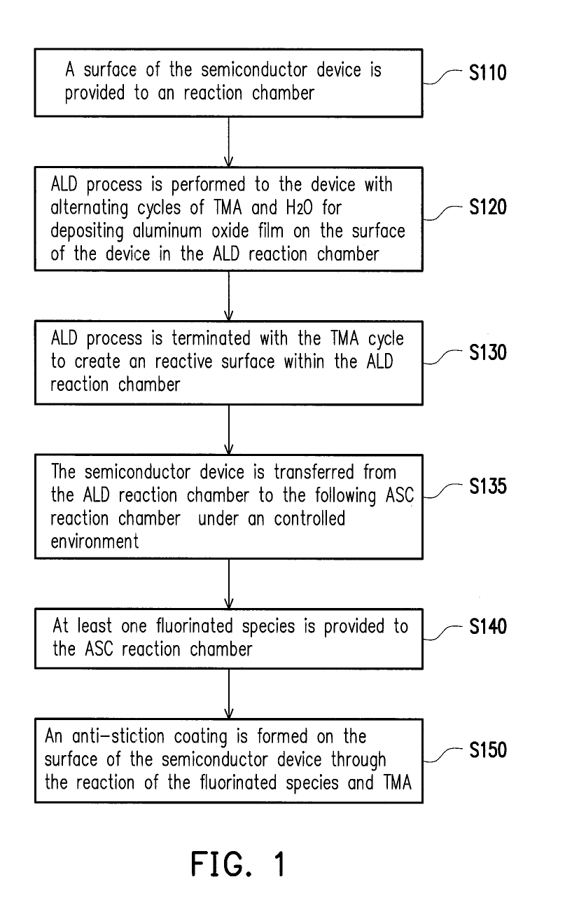

FIG. 1 is a flowchart illustrating a method for forming an anti-stiction coating on a surface of a semiconductor device according to one embodiment of the invention. Referring to FIG. 1, in the present embodiment, the steps of the formation method for the anti-stiction coating is as follows. In step S110, the surface of the semiconductor device is provided to a reaction chamber. Preferably, the semiconductor device may be a MEMS device, particularly MEMS micromirror arrays, for example. In step S120, the ALD process is performed to the device with alternating reaction cycles of TMA and H₂O for depositing the aluminum oxide film on the surface of the device in the ALD reaction chamber (ALD deposition chamber). The numbers of the TMA cycles or H₂O cycles may be altered along with the reaction conditions (e.g. reaction temperature) and depending on the requirements (e.g. thickness, optical and/or electrical properties) of the ALD film. In step S130, the ALD process is terminated with the TMA cycle to create a reactive surface within the ALD reaction chamber. Herein, as mentioned above, the surface of the device is activated by the final TMA cycle and a reactive surface terminated with DMA is created so as to provide a reactive surface terminated or covered with methyl groups.

In step 135, the semiconductor device is transferred from the ALD reaction chamber to the following ASC reaction chamber (ASC deposition chamber) under a controlled environment. Under the controlled environment, the device or the substrate is preserved or isolated by an inert gas (such as N₂ gas) and will not be exposed to air or an ambient environment. In step S140, at least one fluorinated species is provided to the ASC reaction chamber. The fluorinated species may be fluorinated alkaloid acids having at least one carboxyl group (—COOH) and may be perfluorodecanoic acid (PFDA), for example. In Step S150, an anti-stiction coating is formed on the surface of the semiconductor device through the reaction of the carboxyl group of the fluorinated species and the methyl groups on the reaction surface of the device. The carboxyl group of the fluorinated species can react with methyl groups on the reactive surface to form a COO—Al bidentate chemical bond there-between. The fluorinated species (such as PFDA) forms bidentate bonding with TMA. Hence, a self-assembled monolayer (SAM) of the fluorinated species, functioning as the anti-stiction coating (ASC), is formed. Because the bidentate bonding is formed between the fluorinated species and TMA, thermal desorption will occur at higher temperatures when compared to the monodentate bonding. Also, the anti-stiction coating (ASC) formed through the bidentate bonding is much less likely to be dissolved in water. Because the ASC is coated to the surface of the device through strong chemical bonding, the ASC is much more resistant to wear and tear on the MEMS device surface.

In this embodiment, as the ALD process is terminated with the TMA cycle (step S130), the substrate cannot be exposed to air because the TMA reactive surface would degraded and the desired bidentate bonding will not be formed between PFDA and TMA. Although one reaction chamber may be theoretically possible for the ALD process and ASC process, cross-contamination may occur. It is preferred to perform the ALD process and ASC process in separate chambers and transport the substrate or the device between these two chambers under a controlled environment. For example, the transferring of the substrate or the device between two chambers is performed under an inert gas, such as the nitrogen gas, which is not reacted with TMA reactive surface.

In another embodiment, the ALD process is performed using alternating cycles of TMA and H₂O in the ALD chamber for depositing the aluminum oxide film on a surface of a MEMS device and the ALD process is terminated with the exposure of H₂O (i.e. H₂O cycle). The MEMS device or the substrate is then removed from the ALD chamber and placed into the ASC disposition chamber. Afterwards, one TMA cycle of the ALD process is performed to the MEMS device surface within the ASC deposition chamber, so that the surface of the MEMS device is activated and a reactive surface terminated with methyl groups is created. The carboxyl group (—COOH) of the fluorinated species can react with the methyl groups of DMA (Al(CH₃)₂) on the reactive surface to form a COO—Al chemical bonding there-between, so that a self-assembled monolayer (SAM) of the fluorinated species is formed and functions as the anti-stiction coating on the MEMS device surface. In this way, the anti-stiction coating formed through relatively strong bonding on the surface of the MEMS device is established.

By doing so, the ALD process and the ASC coating process (ASC deposition process) can be performed in different chambers, but the reactive surface terminated with methyl groups will not be exposed to ambient air during the transferring procedure.

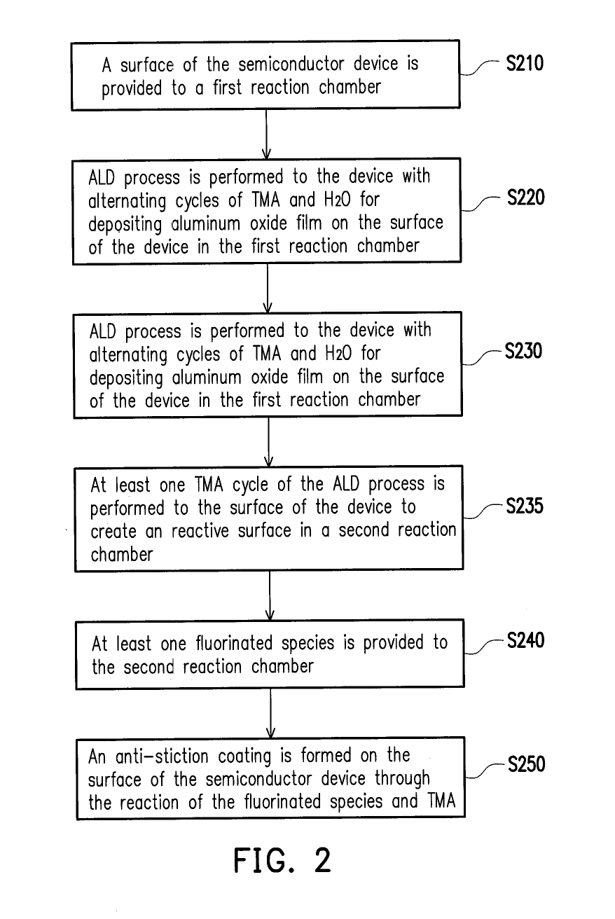

FIG. 2 is a flowchart illustrating a method for forming an anti-stiction coating on a surface of a semiconductor device according to another embodiment of the invention. Referring to FIG. 2, in the present embodiment, the steps of the formation method for the anti-stiction coating is as follows. In step S210, the surface of the semiconductor device is provided to a first reaction chamber. Preferably, the semiconductor device may be a MEMS device, particularly MEMS micromirror arrays, for example. The first reaction chamber is an ALD chamber. In step S220, the ALD process is performed to the device with alternating cycles of TMA and H₂O for depositing the aluminum oxide film on the surface of the device in the first reaction chamber. The numbers of the TMA cycles or H₂O cycles may be altered along with the reaction conditions (e.g. reaction temperature) and depending on the requirements (e.g. thickness, optical and/or electrical properties) of the ALD film. In step S230, the ALD process is terminated with the H₂O cycle within the first reaction chamber. In step S235, at least one TMA cycle of the ALD process is performed to the surface of the semiconductor device create a reactive surface in a second reaction chamber. Herein, the second reaction chamber is an ASC deposition chamber. Following the TMA cycle of the ALD process, the hydroxylated aluminum surface reacts with TMA and one methyl group of TMA coupled with hydrogen (H) of the hydroxyl group (—OH) to form methane gas (CH₄). Herein, TMA (Al(CH₃)₃) losing one methyl group is denoted as dimethylaluminum, DMA, (Al(CH₃)₂). In this case, the aluminum (Al) atom of (Al(CH₃)₂) is bonded to the remaining oxygen of the hydroxyl group of the device surface, while the remaining two methyl groups of (Al(CH₃)₂) are available for the next step to react with the carboxyl group (—COOH) of the fluorinated species to form a bidentate chemical bond. In other words, the device surface is activated and a reactive surface terminated with DMA is created. In step S240, at least one fluorinated species is provided to the second reaction chamber. The fluorinated species may be fluorinated alkanoic acids having at least one carboxyl groups (—COOH) and may be perfluorodecanoic acid (PFDA), for example. In Step S250, an anti-stiction coating is formed on the surface of the semiconductor device through the reaction of the fluorinated species and TMA. The carboxyl group of the fluorinated species can react with TMA on the reactive surface to form a COO—Al chemical bonding there-between. Hence, a self-assembled monolayer (SAM) of the fluorinated species, functioning as the anti-stiction coating (ASC), is formed. Because the ASC is coated to the surface of the device through strong chemical bonding, the ASC is much more resistant to wear and tear on the MEMS device surface.

The wear of the ASC of the present invention after continuous operation is observed by measuring the release curve of lamp stay mode stress and the results are satisfactory.

According to the present invention, the chemistry of the reaction(s) for activating the surface or for forming the anti-stiction coating is simple and reproducible. Also, the resultant anti-stiction coating is mainly monolayered and is chemically bonded to the device surface or substrate. Since the anti-stiction coating is chemically and mechanically stable under conditions of processing and operation, the reliability. In addition, the forming methods of the anti-stiction coating are compatible with semiconductor manufacturing processes.

According to the present invention, there is no need to use excessive fluorinated species to activate the surface before ASC coating process, so that physical damage to the MEMS structure caused by excessive fluorinated species may be minimized and the reliability of the device may be enhanced.

It will be apparent to those skilled in the art that various modifications and variations can be made to the structure of the application without departing from the scope or spirit of the application. In view of the foregoing, it is intended that the application cover modifications and variations of this application provided they fall within the scope of the following claims and their equivalents.

What is claimed is:

1. A method for forming an anti-stiction coating on a surface of a semiconductor device, comprising:
providing the surface of the semiconductor device to a first reaction chamber;
performing an atomic layer deposition (ALD) process to the semiconductor device, wherein the atomic layer deposition process is performed with alternating reaction cycles of trimethylaluminum (TMA) and water (H₂O) for depositing an aluminum oxide film on the surface of the semiconductor device in the first reaction chamber;
terminating the ALD process with one TMA cycle to create a reactive surface within the first reaction chamber;
transferring the semiconductor device from the first reaction chamber to a second reaction chamber under a controlled environment;
providing at least one fluorinated species to the second reaction chamber; and
forming an anti-stiction coating on the surface of the semiconductor device through reactions of the fluorinated species and TMA.

2. The method as claimed in claim 1, wherein the semiconductor device is a MEMS device or a micromirror array.

3. The method as claimed in claim 1, wherein the fluorinated species includes a fluorinated alkanoic acid having at least one carboxyl group (—COOH).

4. The method as claimed in claim 3, wherein the fluorinated species is perfluorodecanoic acid (PFDA).

5. The method as claimed in claim 3, wherein the at least one carboxyl group of the fluorinated alkanoic acid of the fluorinated species reacts with methyl groups on the reactive surface from TMA and a chemical bonding is established there-between.

6. The method as claimed in claim 5, wherein the chemical bonding is a bidentate chemical bonding.

7. A method for forming an anti-stiction coating on a surface of a semiconductor device, comprising:
providing the surface of the semiconductor device to a first reaction chamber;
performing an atomic layer deposition (ALD) process to the semiconductor device, wherein the atomic layer deposition process is performed with alternating reaction cycles of trimethylaluminum (TMA) and water (H₂O) for depositing an aluminum oxide film on the surface of the semiconductor device in the first reaction chamber;
terminating the ALD process with one water cycle in the first reaction chamber;
performing at least one TMA cycle of the ALD process to the surface of the semiconductor device to create a reactive surface in a second reaction chamber;
providing at least one fluorinated species to the second reaction chamber; and
forming an anti-stiction coating on the surface of the semiconductor device through reactions of the fluorinated species and TMA.

8. The method as claimed in claim 7, wherein the semiconductor device is a MEMS device or a micromirror array.

9. The method as claimed in claim 7, wherein the fluorinated species includes a fluorinated alkanoic acid having at least one carboxyl group (—COOH).

10. The method as claimed in claim 9, wherein the fluorinated species is perfluorodecanoic acid (PFDA).

11. The method as claimed in claim 9, wherein the at least one carboxyl group of the fluorinated alkanoic acid of the fluorinated species reacts with methyl groups on the reactive surface from TMA and a chemical bonding is established there-between.

12. An anti-stiction coating, disposed on a surface of a semiconductor device, wherein the anti-stiction coating is obtained by the formation method of claim 1.

13. An anti-stiction coating, disposed on a surface of a semiconductor device, wherein the anti-stiction coating is obtained by the formation method of claim 7.
